(19) United States
(12) Patent Application Publication
(10) Pub. No.: US 2009/0212826 A1
(43) Pub. Date: Aug. 27, 2009

(54) HYSTERESIS COMPARATOR

(75) Inventor: Sunao MIZUNAGA, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/358,273

(22) Filed: Jan. 23, 2009

(30) Foreign Application Priority Data
Feb. 22, 2008 (JP) 2008-041825

(51) Int. Cl. G01R 19/30

(52) U.S. Cl. 327/62

(57) ABSTRACT

Disclosed herein is a hysteresis comparator for performing a binarization determination with respect to an input signal having a consecutively varying voltage level based on two threshold voltages having different voltage levels and generating an output signal based on a result of the determination. The hysteresis comparator includes a top peak detector for detecting a top peak of the input signal and generating a top peak detect voltage based on the detected top peak, a bottom peak detector for detecting a bottom peak of the input signal and generating a bottom peak detect voltage based on the detected bottom peak, a threshold voltage generator for generating the first and second threshold voltages within a range between a voltage level of the top peak detect voltage and a voltage level of the bottom peak detect voltage, and a voltage comparison circuit for comparing the voltage level of the input signal with the voltage levels of the first and second threshold voltages to perform the binarization determination with respect to the input signal, and generating the output signal based on the determination result.

### BACKGROUND OF THE INVENTION

1. Field of the Invention

The present invention relates to a hysteresis comparator for performing a binarization determination with respect to an input signal based on two threshold voltages having different voltage levels.

2. Description of the Related Art

FIG. 1 shows an example of the configuration of a hysteresis comparator that is generally used. The hysteresis comparator comprises an operational (OP) amplifier 1, a resistor RA having one end connected to a non-inverting input terminal of the OP amplifier 1, and a resistor RB having one end connected to an output terminal of the OP amplifier 1 and the other end connected to the non-inverting input terminal. A reference voltage Vref is applied to the other end of the resistor RA and an input signal Vin is supplied to an inverting input terminal of the OP amplifier 1. Applied to the non-inverting input terminal of the OP amplifier 1 is a threshold voltage Va obtained by dividing a voltage corresponding to a difference between an output signal Vout and the reference voltage Vref by means of the resistors RA and RB. The hysteresis comparator outputs a low-level output signal VOL when the input signal Vin exceeds the threshold voltage Va, and a high-level output signal VOH when the input signal Vin does not reach the threshold voltage Va. That is, the output signal Vout makes a transition to a low level (VOL) when Vin>Vref+(Vout−Vref)×RA/(RA+RB), and a transition to a high level (VOH) when Vin<Vref−(Vout+Vref)×RA/(RA+RB). As a result, the hysteresis comparator has a hysteresis characteristic where a threshold voltage when the output signal thereof is changed from the high level to the low level and a threshold voltage when the output signal thereof is changed from the low level to the high level are different. Here, a difference between the threshold voltages, namely, a hysteresis width can be expressed by (VOH−VOL)×RA/(RA+RB).

FIG. 2A shows waveforms of input and output signals of a comparator which does not have this hysteresis characteristic. In the comparator having no hysteresis characteristic, as shown in FIG. 2A, if an input signal containing a noise component is supplied to an input terminal, a so-called chattering where the inversion of an output signal is frequently repeated occurs when the voltage level of the input signal is in the vicinity of a threshold voltage, thereby making it impossible to obtain a stable output signal. FIG. 2B shows waveforms of input and output signals of a hysteresis comparator having the hysteresis characteristic. By using this hysteresis comparator, even when an input signal Vin contains a noise component, a threshold voltage varies by a hysteresis width once the output signal is inverted, thereby preventing an output signal inversion resulting from the noise component, thus making it possible to prevent the chattering from occurring (see Japanese Patent Laid-open Publication Kokai No. 2002-171159, for example).

However, in the conventional hysteresis comparator with the above-mentioned configuration, because the hysteresis width is a fixed value set by the resistors RA and RB, the output signal of the comparator is subject to no variation when the amplitude of the input signal is smaller than the set hysteresis width. As a result, in the conventional hysteresis comparator, there is a need to set a proper threshold voltage and a proper hysteresis width after grasping the amplitude of the input signal in advance, and it may be impossible to obtain a proper output signal when the amplitude of the input signal is smaller than a target value. In detail, as shown in FIG. 3, when the amplitude of an input signal actually supplied to the hysteresis comparator is subject to a variation with respect to original input data due to degradation in S/N ratio, etc., the peak of a waveform of the input signal may fail to exceed a threshold voltage provided that a hysteresis width is fixed (a part A of FIG. 3). As a result, the output signal may not be inverted at a part in which the output signal must be originally inverted, thus making it impossible to completely reproduce the original input data (a part B of FIG. 3).

### SUMMARY OF THE INVENTION

Therefore, the present invention has been made in view of the above mentioned problems, and it is an object of the present invention to provide a hysteresis comparator which is capable of obtaining a proper output signal even when the amplitude of an input signal is smaller than a target value or it is subject to a variation.

In accordance with the present invention, the above and other objects can be accomplished by the provision of a hysteresis comparator for performing a binarization determination with respect to an input signal having a consecutively varying voltage level based on two threshold voltages having different voltage levels and generating an output signal based on a result of the determination, the hysteresis comparator comprising: a top peak detector for detecting a top peak of the input signal and generating a top peak detecting voltage based on the detected top peak; a bottom peak detector for detecting a bottom peak of the input signal and generating a bottom peak detecting voltage based on the detected bottom peak; a threshold voltage generator for generating the first and second threshold voltages within a range between a voltage level of the top peak detecting voltage and a voltage level of the bottom peak detecting voltage; and a voltage comparison circuit for comparing the voltage level of the input signal with the voltage levels of the first and second threshold voltages to perform the binarization determination with respect to the input signal, and generating the output signal based on the determination result.

According to a hysteresis comparator of the present invention, the voltage levels of two threshold voltages Vth1 and Vth2 constituting a hysteresis characteristic are set within a range between the voltage levels of a top peak and bottom peak of a input signal to be compared, and consecutively changed whenever a peak detection is made with respect to the input signal. As a result, the threshold voltages Vth1 and Vth2 always maintain proper levels with respect to the input signal. Therefore, it is possible to obtain a proper output signal even when the amplitude of the input signal is smaller than a target value or it is subject to a variation.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a circuit diagram showing the configuration of a conventional hysteresis comparator;

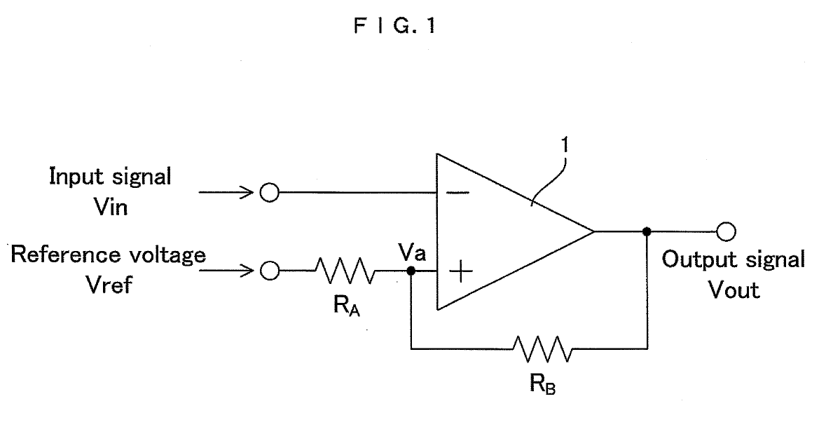

FIG. 2A is a waveform diagram of input and output signals of a comparator having no hysteresis characteristic;

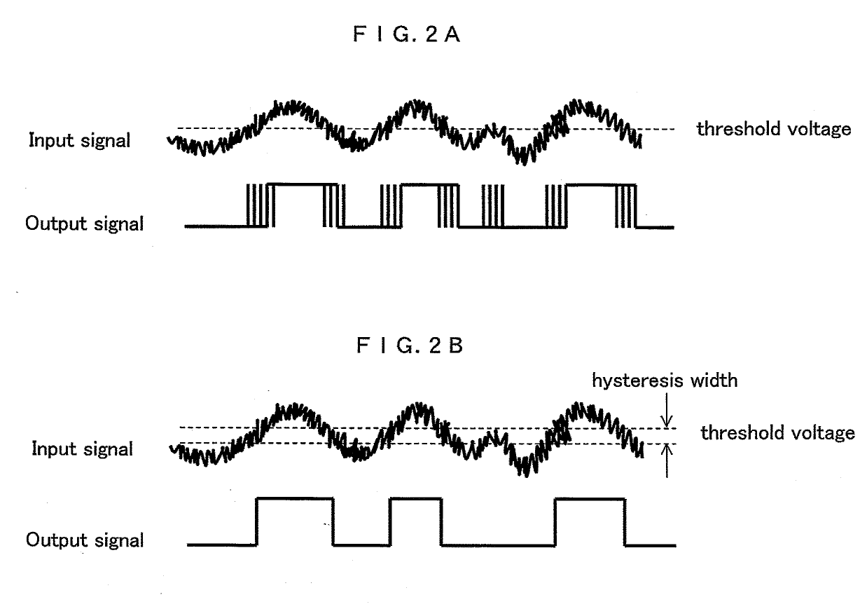

FIG. 2B is a waveform diagram of input and output signals of a hysteresis comparator;

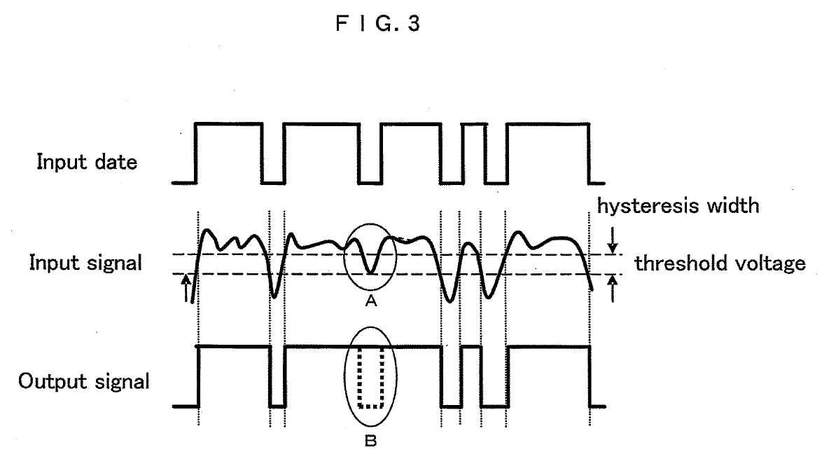

FIG. 3 is a waveform diagram of input and output signals of the conventional hysteresis comparator when the amplitude of the input signal is subject to a variation;

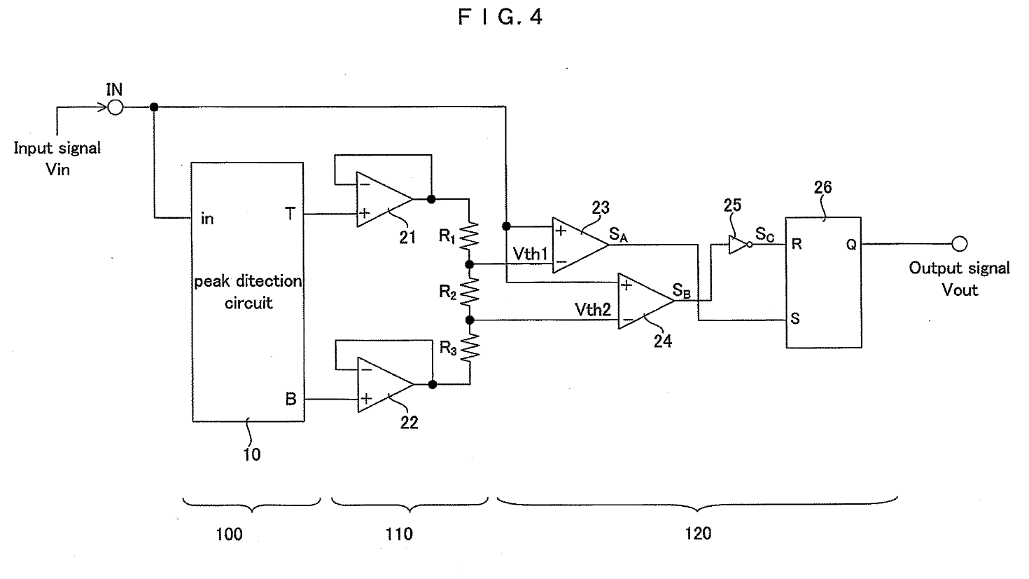

FIG. 4 is a circuit diagram showing the configuration of a hysteresis comparator according to a first embodiment of the present invention;

FIG. 5 is a circuit diagram of a peak detection circuit of the hysteresis comparator according to the first embodiment of the present invention;

FIG. 6 is a waveform diagram of input and output signals of the hysteresis comparator according to the first embodiment of the present invention;

FIG. 7 is a timing chart illustrating the operation of a voltage comparison circuit of the hysteresis comparator according to the first embodiment of the present invention;

FIG. 8 is a circuit diagram showing the configuration of a hysteresis comparator according to a second embodiment of the present invention;

FIG. 9 is a circuit diagram of variable resistors according to the second embodiment of the present invention;

FIG. 10 is a waveform diagram illustrating the operation of a peak detection circuit according to the second embodiment of the present invention;

FIG. 11 is a circuit diagram of a peak detection circuit according to a third embodiment of the present invention; and

FIGS. 12A and 12B are waveform diagrams illustrating the operation of the peak detection circuit according to the third embodiment of the present invention.

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

### First Embodiment

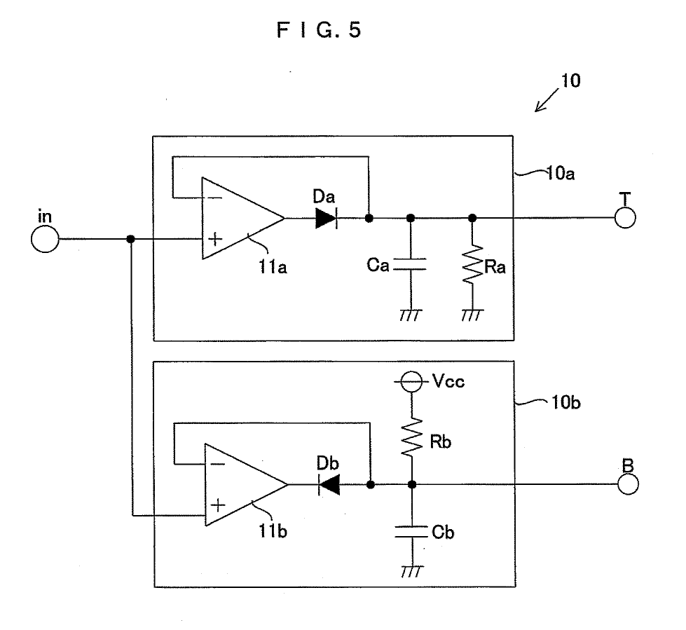

FIG. 4 is a circuit diagram showing the configuration of a hysteresis comparator according to a first embodiment of the present invention. The circuit configuration of the hysteresis comparator according to the present embodiment is broadly divided into three function parts. That is, the hysteresis comparator according to the present embodiment comprises a peak detector 100 for detecting a top peak and bottom peak of an input signal Vin to be compared and outputting detecting voltages corresponding respectively to the detected peaks, a threshold voltage generator 110 for generating threshold voltages Vth1 and Vth2 having different voltage levels based on the detecting voltages of both peaks generated by the peak detector 100, and a voltage comparison circuit 120 for comparing the input signal Vin with the threshold voltages Vth1 and Vth2 generated by the threshold voltage generator 110 to perform a binarization determination with respect to the input signal Vin, and generating an output signal based on the determination result.

Hereinafter, the respective function parts will be described in detail. The peak detector 100 is composed of a peak detection circuit 10. The peak detection circuit 10 has an input terminal “in” connected to an input terminal “IN” of the hysteresis comparator to which the input signal Vin is inputted, a top peak output terminal “T”, and a bottom peak output terminal “B”. The peak detection circuit 10 detects a top peak within a certain period from the input signal Vin and outputs a top peak detecting voltage corresponding to the detected top peak at the top peak output terminal “T”. Also, the peak detection circuit 10 detects a bottom peak within a certain period from the input signal Vin and outputs a bottom peak detecting voltage corresponding to the detected bottom peak at the bottom peak output terminal “B”.

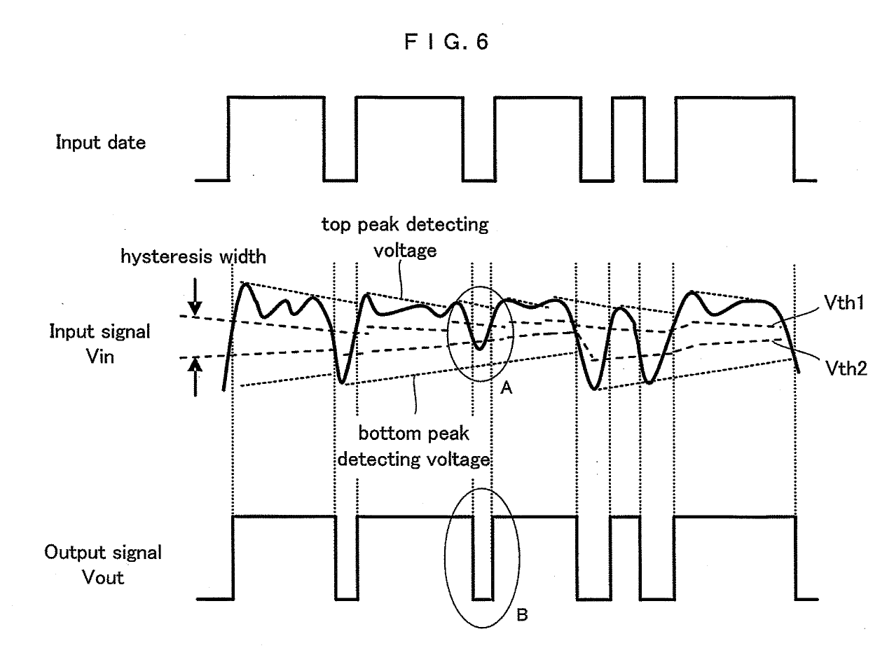

FIG. 5 is a detailed circuit diagram of the peak detection circuit 10.

The peak detection circuit 10 includes a top peak detector 10a and a bottom peak detector 10b. The top peak detector 10a includes an OP amplifier 11a, a diode Dₐ having an anode connected to an output terminal of the OP amplifier 11a, and a discharging resistor Rₐ and a hold capacitor Cₐ connected between a cathode of the diode Dₐ and a ground terminal. The OP amplifier 11a has a non-inverting input terminal connected to the input terminal “in” of the peak detection circuit 10. The cathode of the diode Dₐ is connected to the top peak output terminal “T”. The OP amplifier 11a also has an inverting input terminal connected to the top peak output terminal “T”. On the other hand, the bottom peak detector 10b includes an OP amplifier 11b, a diode D_{b} having a cathode connected to an output terminal of the OP amplifier 11b, a hold capacitor C_{b} connected between an anode of the diode D_{b} and the ground terminal, and a charging resistor R_{b} connected between a supply voltage Vcc and the cathode of the diode D_{b}. The OP amplifier 11b has a non-inverting input terminal connected to the input terminal “in” of the peak detection circuit 10. The anode of the diode D_{b} is connected to the bottom peak output terminal “B”. The OP amplifier 11b also has an inverting input terminal connected to the bottom peak output terminal “B”.

In the top peak detector 10a, the charging voltage of the capacitor Cₐ is 0V in an initial state. When the input signal Vin is applied to the input terminal “in”, the potential of the non-inverting input terminal of the OP amplifier 11a becomes higher than the potential of the inverting input terminal of the OP amplifier 11a, so that the output voltage of the OP amplifier 11a is swung positively. Then, the diode Dₐ conducts, so as to charge the hold capacitor Cₐ, and a potential corresponding to the voltage level of the input signal Vin thus appears at the top peak output terminal “T”. As a result, the potential of the inverting input terminal of the OP amplifier 11a also becomes the voltage level of the input signal Vin, so that the output voltage of the OP amplifier 11a becomes 0V. At this time, the diode Dₐ is reverse-biased, thereby causing no charging current to flow to the hold capacitor Cₐ. Because charges stored in the hold capacitor Cₐ are discharged through the discharging resistor Ra, the potential at the top peak output terminal “T” falls with a certain time constant. At the time that the input signal Vin has a voltage level (top peak) higher than the potential at the top peak output terminal “T”, the diode Dₐ conducts again, so that a potential corresponding to the new top peak level appears at the top peak output terminal “T”. By setting a discharging time constant determined by a circuit constant of the hold capacitor Cₐ and discharging resistor Rₐ to be adequately higher than the frequency of the input signal Vin, the top peak detector 10a can be considered to substantially hold the top peak of the input signal waveform. In this manner, the top peak detector 10a detects a top peak within a certain period from the supplied input signal Vin and outputs a voltage corresponding to the detected top peak as a top peak detecting voltage.

In the bottom peak detector 10b, the capacitor C_{b} is charged with the supply voltage Vcc in the initial state. When the input signal Vin is applied to the input terminal “in”, the potential of the non-inverting input terminal of the OP amplifier 11b becomes lower than the potential of the inverting input terminal of the OP amplifier 11b, so that the output voltage of the OP amplifier 11b falls to follow the input signal Vin. Then, the diode D_{b} conducts, so that charges stored in the hold capacitor C_{b} are discharged through the diode D_{b}, and a potential corresponding to the voltage level of the input signal Vin thus appears at the bottom peak output terminal “B”. As a result, the potential of the inverting input terminal of the OP amplifier 11b also becomes the voltage level of the input signal Vin, so that the diode D_{b} becomes nonconductive and the discharging of the hold capacitor C_{b} is thus stopped. Then, charging current begins to flow to the hold capacitor C_{b} through the charging resistor R_{b}, so as to charge the hold capacitor C_{b}. As a result, the potential at the bottom peak output terminal “B” rises with a certain time constant. At the time that the input signal Vin has a voltage level (bottom peak) lower than the potential at the bottom peak output terminal “B”, charges stored in the hold capacitor C_{b} are again discharged, so that a potential corresponding to the new bottom peak level appears at the bottom peak output terminal “B”. By setting a charging time constant determined by a circuit constant of the hold capacitor C_{b} and charging resistor R_{b} to be adequately higher than the frequency of the input signal Vin, the bottom peak detector 10b can be considered to substantially hold the bottom peak of the input signal waveform. In this manner, the bottom peak detector 10b detects a bottom peak within a certain period from the supplied input signal Vin and outputs a voltage corresponding to the detected bottom peak as a bottom peak detecting voltage.

The threshold voltage generator 110 includes buffer circuits 21 and 22 connected respectively to the top peak output terminal “T” and the bottom peak output terminal “B”, and resistors R₁, R₂ and R₃ connected between output terminals of the buffer circuits 21 and 22. The buffer circuits 21 and 22 are composed of voltage followers and receive the voltages charged on the hold capacitors Ca and Cb with high input impedances, respectively. The buffer circuits 21 and 22 output the top peak detecting voltage generated at the top peak output terminal “T” and the bottom peak detecting voltage generated at the bottom peak output terminal “B” as they are, respectively. A voltage generated between the top peak output terminal “T” and the bottom peak output terminal “B” is applied across a series resistor circuit consisting of the resistors R1, R2 and R3 connected in series and divided by the series resistor circuit. A first threshold voltage Vth1 is extracted from a connection point of the resistors R1 and R2 and a second threshold voltage Vth2 is extracted from a connection point of the resistors R2 and R3. A relationship of Vth1>Vth2 is always established between the first threshold voltage Vth1 and the second threshold voltage Vth2.

The voltage comparison circuit 120 includes a first comparator 23 having a non-inverting input terminal connected to the input terminal “IN” and an inverting input terminal connected to the connection point of the resistors R1 and R2, a second comparator 24 having a non-inverting input terminal connected to the input terminal “IN” and an inverting input terminal connected to the connection point of the resistors R2 and R3, an inverter 25 connected to an output terminal of the second comparator 24, and an RS flip-flop 26 for receiving an output signal S_{A} from the first comparator 23 at a set input terminal thereof and an output signal S_{C} from the inverter 25 at a reset input terminal thereof. The first comparator 23 performs a binarization determination with respect to the input signal Vin based on the threshold voltage Vth1 generated by the threshold voltage generator 110 as a comparison reference voltage and outputs the determination result as the output signal S_{A}. The second comparator 24 performs a binarization determination with respect to the input signal Vin based on the threshold voltage Vth2 generated by the threshold voltage generator 110 as a comparison reference voltage and outputs the determination result as an output signal S_{B}. That is, each of the first and second comparators 23 and 24 outputs a high-level output signal when the supplied input signal Vin is higher than the threshold voltage Vth1 or Vth2, and a low-level output signal when the supplied input signal Vin is lower than the threshold voltage Vth1 or Vth2. The inverter 25 inverts the output signal S_{B} from the second comparator 24 and outputs the inverted signal as the output signal S_{C}. An output signal Vout outputted from the RS flip-flop 26 is a final output signal Vout of the hysteresis comparator according to the present embodiment. Also, the aforementioned conventional hysteresis comparator may be used as each of the first and second comparators.

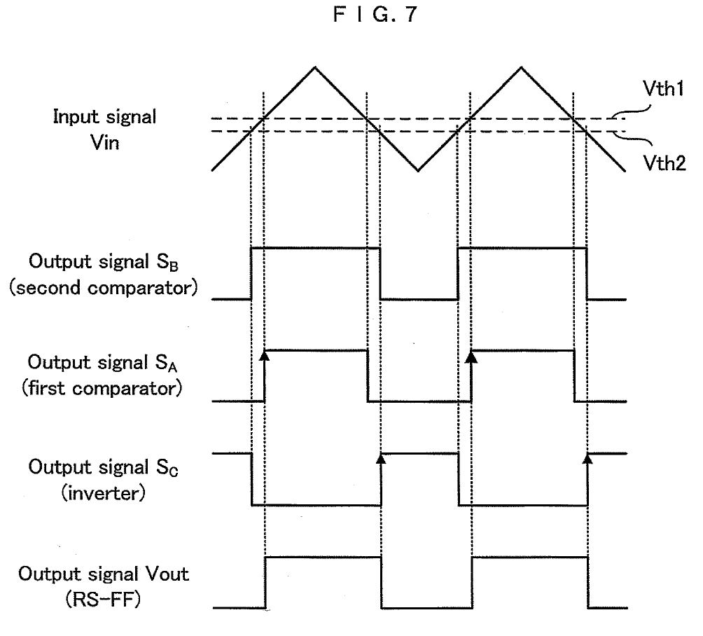

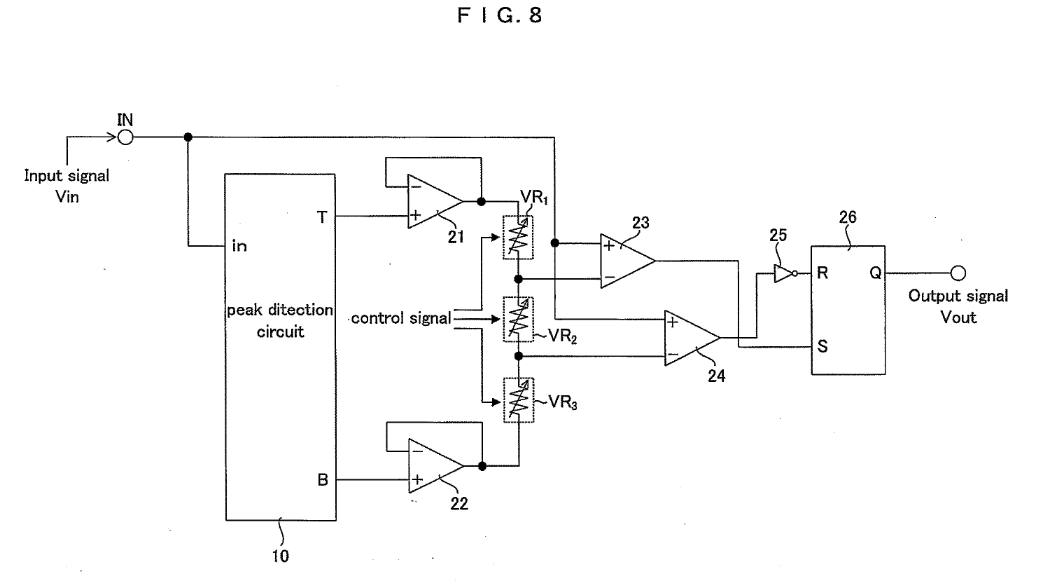

Next, the operation of the hysteresis comparator according to the present embodiment will be described with reference to FIGS. 6 and 7. FIG. 6 shows waveforms of input data, the input signal Vin and output signal Vout of the hysteresis comparator according to the present embodiment, the top peak detecting voltage and bottom peak detecting voltage generated by the peak detection circuit 10 and the first and second threshold voltages generated by the threshold voltage generator 110. The input signal Vin is generated based on the input data by a signal generator, not shown, and received by the hysteresis comparator according to the present embodiment. It is assumed here that the input signal Vin is deteriorated in waveform quality due to environments on a signal transmission path and thus suffers a waveform distortion with respect to the original input data, as shown in FIG. 6. The peak detection circuit 10 detects the top peak of the supplied input signal Vin and outputs the top peak detecting voltage corresponding to the detected top peak at the top peak output terminal “T”. Because the outputted top peak detecting voltage is discharged through the discharging resistor Rₐ of the top peak detector 10a, the level thereof falls in a certain ratio. The top peak detecting voltage is updated when the voltage level of the input signal Vin has exceeded the potential generated at the top peak output terminal “T”. Also, the peak detection circuit 10 detects the bottom peak of the supplied input signal Vin and outputs the bottom peak detecting voltage corresponding to the detected bottom peak at the bottom peak output terminal “B”. Because the hold capacitor C_{b} of the bottom peak detector 10b is charged through the charging resistor R_{b}, the outputted bottom peak detecting voltage rises in a certain ratio. The bottom peak detecting voltage is updated when the voltage level of the input signal Vin has not reached the potential generated at the bottom peak output terminal “B”.

The top peak detecting voltage and the bottom peak detecting voltage are outputted through the buffer circuits 21 and 22 while the levels thereof are maintained as they are, respectively. The top peak detecting voltage and the bottom peak detecting voltage generated respectively at the output terminals of the buffer circuits 21 and 22 are divided by the resistors R1, R2 and R3, and the first threshold voltage Vth1 is extracted from the connection point of the resistors R1 and R2 and the second threshold voltage Vth2 is extracted from the connection point of the resistors R2 and R3. That is, both the first and second threshold voltages are set to voltage levels which are higher than the bottom peak detecting voltage level and lower than the top peak detecting voltage level. Therefore, it is next to impossible that the first threshold voltage Vth1 is higher than the top peak of the input signal Vin and the second threshold voltage Vth2 is lower than the bottom peak of the input signal Vin. Also, because each of the top peak detecting voltage and the bottom peak detecting voltage is updated whenever a new peak appears at the input signal Vin as stated above, the threshold voltages Vth1 and Vth2 also vary accordingly. That is, the first and second threshold voltages and the hysteresis width therebetween are controlled to vary following the top peak and bottom peak of the input signal Vin so as to always maintain proper voltage levels with respect to the input signal Vin.

FIG. 7 is a timing chart showing waveforms of the respective signals in the voltage comparison circuit 120. For a better understanding of the operation of the voltage comparison circuit 120, a triangle wave signal is used as the input signal Vin in FIG. 7. When the input signal Vin rises and then exceeds the second threshold voltage Vth2, the output signal S_{B} from the second comparator 24 becomes high in level. The inverter 25 inverts this high-level output signal S_{B} and outputs a low-level output signal S_{C}. At this time, the output signal S_{A} from the first comparator 23 is kept low in level. When the input signal Vin further rises and then exceeds the first threshold voltage Vth1, the output signal S_{A} from the first comparator 23 becomes high in level. If the output signal S_{A} from the first comparator 23 becomes high in level, the RS flip-flop 26 is set, thus making the output signal Vout high in level. Thereafter, when the input signal Vin begins to fall and then becomes lower than the first threshold voltage Vth1, the output signal S_{A} from the first comparator 23 becomes low in level. At this time, the output signal S_{B} from the second comparator 24 is kept high in level. When the input signal Vin further falls and then becomes lower than the second threshold voltage Vth2, the output signal S_{B} from the second comparator 24 becomes low in level. The inverter 25 inverts this low-level output signal S_{B} and outputs a high-level output signal S_{C}. If the output signal S_{C} becomes high in level, the RS flip-flop 26 is reset, thus making the output signal Vout low in level. The output signal Vout is kept low in level until a next set signal is supplied. That is, the output signal Vout of the hysteresis comparator goes high in level when the input signal Vin becomes higher than the first threshold voltage Vth1, and low in level when the input signal Vin becomes lower than the second threshold voltage Vth2. In this manner, in the hysteresis comparator according to the present embodiment, a hysteresis characteristic is realized by the operation of the voltage comparison circuit 120, thereby preventing a chattering from occurring in the output signal Vout due to noise contained in the input signal Vin, etc.

The bottom part of FIG. 6 shows an output signal Vout when an input signal Vin and threshold voltages Vth1 and Vth2 as shown in the middle part of FIG. 6 are supplied to the voltage comparison circuit 120 operating in the above manner. The voltage comparison circuit 120 outputs the result of comparison between the supplied input signal Vin and the threshold voltages Vth1 and Vth2 varying following the top peak and bottom peak of the input signal Vin as the output signal Vout. As stated above, the voltage levels of the threshold voltages Vth1 and Vth2 are set within a range between the voltage levels of the top peak and bottom peak of the input signal Vin and consecutively updated whenever the peak detection is made with respect to the input signal Vin. As a result, the threshold voltages Vth1 and Vth2 always maintain proper levels with respect to the input signal Vin, thereby solving a conventional problem that a proper comparison process cannot be performed because the amplitude of the input signal is so small that it cannot exceed a threshold voltage. Particularly, even in the case where the amplitude of the input signal is subject to a variation resulting from deterioration in waveform quality due to degradation in S/N ratio, etc. (a part A of FIG. 6), because the threshold voltages and the hysteresis width are set based on the peak voltage levels of the input signal Vin, a proper output signal can be detected and obtained (a part B of FIG. 6) even with respect to an input signal for which the detection was not able to be made by a conventional hysteresis comparator that performs a binarization determination based on a fixed threshold voltage and a fixed hysteresis width.

### Second Embodiment

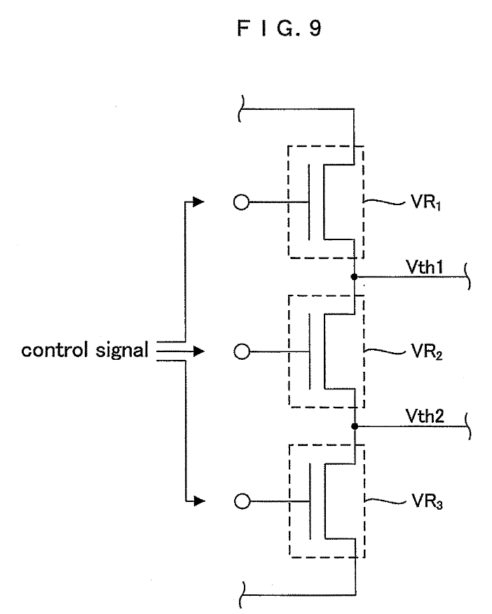

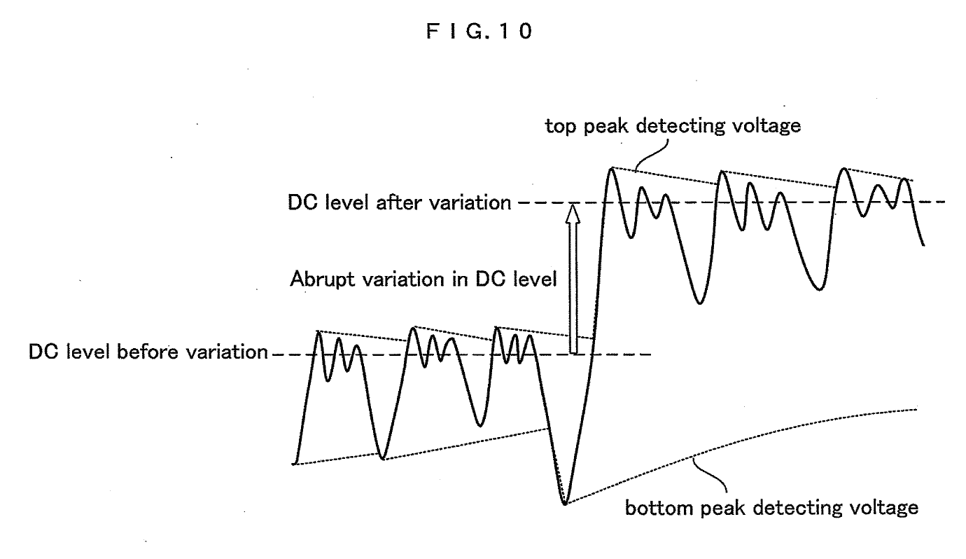

FIG. 8 is a circuit diagram showing the configuration of a hysteresis comparator according to a second embodiment of the present invention. The hysteresis comparator according to the second embodiment is the same in basic configuration and basic operation as that according to the first embodiment. Hereinafter, a description will be given of only parts of the second embodiment different from those of the first embodiment. In the hysteresis comparator according to the second embodiment, variable resistors VR1, VR2 and VR3 connected in series are connected between the output terminals of the buffer circuits 21 and 22. The resistance of each of the variable resistors VR1 to VR3 can be controlled by a control signal externally supplied. Each of the variable resistors VR1 to VR3 may be composed of, for example, a field effect transistor (FET) as shown in FIG. 9. By individually supplying control signals to gates of the FETs constituting the variable resistors VR1 to VR3, the variable resistors VR1 to VR3 have resistances based on signal levels of the control signals, respectively.

As described above, in the present embodiment, the variable resistors VR1 to VR3 are provided as voltage-dividing resistors for dividing a voltage between the top peak and bottom peak of the input signal Vin, so that the voltage level of a first threshold voltage Vth1 extracted from a connection point of the variable resistors VR1 and VR2, the voltage level of a second threshold voltage Vth2 extracted from a connection point of the variable resistors VR2 and VR3, and a hysteresis width are variable. Therefore, it is possible to adjust the threshold voltages Vth1 and Vth2 and the hysteresis width depending on the level of an amplitude variation of the input signal Vin or the pulse width of an output signal Vout obtained as a result of a binarization determination with respect to the input signal Vin. Even in this case, the threshold voltages Vth1 and Vth2 are set within a range between the top peak detecting voltage and the bottom peak detecting voltage and a relationship of Vth1>Vth2 is established. In addition, several patterns of a control signal to be supplied to each of the variable resistors VR1 to VR3 may be pre-stored and one of the pre-stored control signal patterns may be selected and supplied according to a given situation.

### Third Embodiment

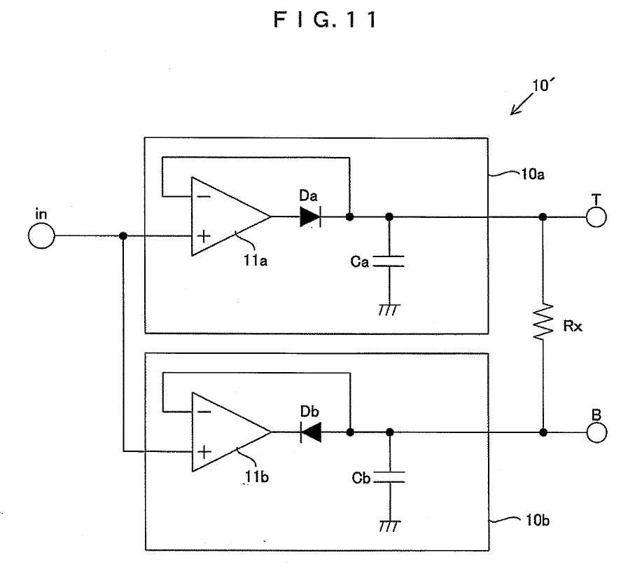

The peak detection circuit 10 configured as shown in FIG. 5, used in the hysteresis comparators of the first and second embodiments, can be considered to have a problem as will hereinafter be described. That is, in the peak detection circuit 10, the top peak detector 10a and the bottom peak detector 10b detect the top peak and bottom peak of the input signal Vin, respectively, independently of each other. For this reason, for example, if the DC level of the input signal Vin rises abruptly as shown in FIG. 10, the bottom peak detecting voltage is maintained for a lengthy period of time, not updated, because the input signal Vin cannot reach a level lower than the previously updated bottom peak detecting voltage. As a result, the input signal Vin after the DC level thereof rises is subject to a binarization determination by a threshold voltage set based on the maintained bottom peak detecting voltage, so that the bottom peak of the input signal Vin after DC level variation cannot exceed this threshold voltage, resulting in a concern that a proper output signal could not be obtained. The abrupt variation in the DC level of the input signal Vin may occur, for example, when the direction of a radio receiver of a radio-controlled clock varies abruptly in the case where the hysteresis comparator of the present invention is installed in the radio receiver. A third embodiment of the present invention provides an improved peak detection circuit in view of this fact.

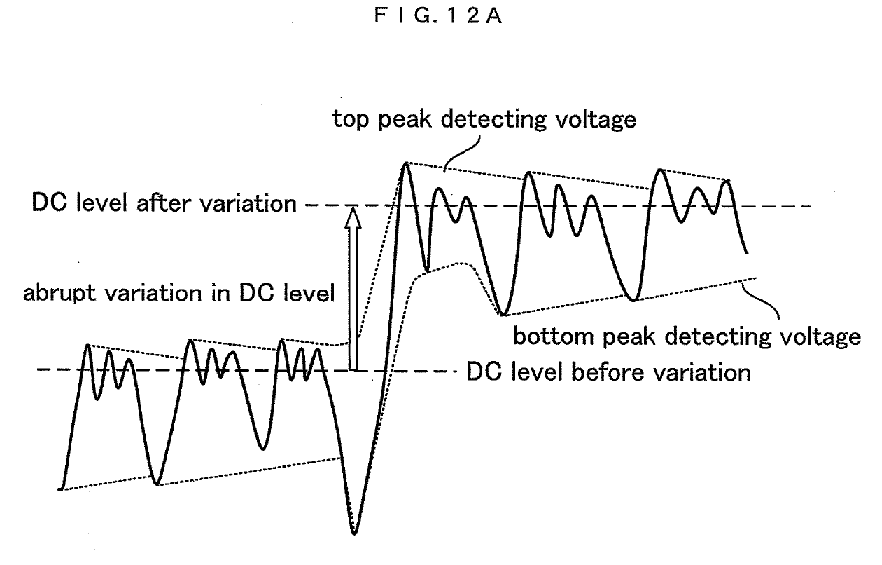

FIG. 11 shows the configuration of a peak detection circuit 10′ used in a hysteresis comparator according to the third embodiment of the present invention. Compared with that used in the first and second embodiments, in the peak detection circuit 10′ according to the present embodiment, the discharging resistor Rₐ connected in parallel to the hold capacitor Cₐ and the charging resistor R_{b} connected in series to the hold capacitor C_{b} are removed and the top peak output terminal “T” and the bottom peak output terminal “B” are interconnected via a resistor Rₓ. The constituent elements of the third embodiment other than the peak detection circuit are the same as those of the first or second embodiment and a description thereof will thus be omitted. By configuring the peak detection circuit in this manner, charges stored in the hold capacitors Cₐ and C_{b} can move through the resistor Rₓ and the potential of each output terminal varies following a potential variation of the other output terminal.

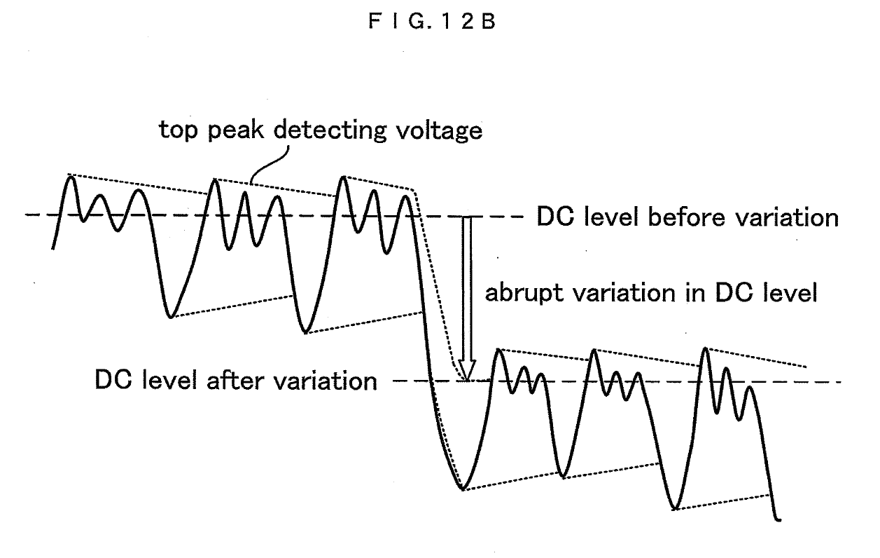

FIGS. 12A and 12B show a top peak detecting voltage and a bottom peak detecting voltage generated by the peak detection circuit 10′ in the case where an input signal Vin accompanied with an abrupt DC level variation is supplied to the peak detection circuit 10′, in which FIG. 12A shows the case where the DC level of the input signal Vin rises abruptly. As shown in FIG. 12A, in the peak detection circuit 10′ according to the present embodiment, even in the case where the DC level of the input signal Vin rises abruptly, if the top peak detecting voltage rises by this DC level variation, the bottom peak detecting voltage also rises to follow it. At this time, charges move from the top peak output terminal “T” to the bottom peak output terminal “B” through the resistor Rₓ, and the potential of the top peak output terminal “T” falls, whereas the potential of the bottom peak output terminal “B” rises. A charge moving speed, or discharging time constant, is determined based on the resistance of the resistor Rₓ. Also, the discharging time constant can be adjusted by providing a variable resistor as the resistor Rₓ. FIG. 12B shows the case where the DC level of the input signal Vin falls abruptly. As shown in FIG. 12B, in the peak detection circuit 10′ according to the present embodiment, if the DC level of the input signal Vin falls abruptly and the bottom peak detecting voltage falls accordingly, the top peak detecting voltage also falls to follow it. Also, in this case, charges move from the top peak output terminal “T” to the bottom peak output terminal “B” through the resistor Rₓ, and the potential of the bottom peak output terminal “B” rises, whereas the potential of the top peak output terminal “T” falls.

As described above, in the peak detection circuit according to the present embodiment, the output voltages from the top peak output terminal “T” and bottom peak output terminal “B” vary to follow each other's voltage variations. Therefore, even when the DC level of the input signal varies abruptly, the threshold voltages Vth1 and Vth2 are controlled to have proper levels corresponding to the input signal after the variation. That is, according to the peak detection circuit of the present embodiment, it is possible to solve the above problem that a proper output signal cannot be obtained due to the abrupt DC level variation of the input signal.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

This application is based on Japanese Patent Application No. 2008-041825, which is hereby incorporated by reference as if fully set forth herein.

What is claimed is:

1. A hysteresis comparator for performing a binarization determination with respect to an input signal having a consecutively varying voltage level based on two threshold voltages having different voltage levels and generating an output signal based on a result of the determination, the hysteresis comparator comprising:
a top peak detector for detecting a top peak of the input signal and generating a top peak detecting voltage based on the detected top peak;
a bottom peak detector for detecting a bottom peak of the input signal and generating a bottom peak detecting voltage based on the detected bottom peak;
a threshold voltage generator for generating the first and second threshold voltages within a range between a voltage level of the top peak detecting voltage and a voltage level of the bottom peak detecting voltage; and
a voltage comparison circuit for comparing the voltage level of the input signal with the voltage levels of the first and second threshold voltages to perform the binarization determination with respect to the input signal, and generating the output signal based on the determination result.

2. The hysteresis comparator according to claim 1, wherein the threshold voltage generator comprises a series resistor having both ends to which the top peak detecting voltage and the bottom peak detecting voltage are applied, respectively, the series resistor comprising a plurality of resistive elements including connection points for outputting the first and second threshold voltages, respectively.

3. The hysteresis comparator according to claim 2, wherein each of the resistive elements is a variable resistor.

4. The hysteresis comparator according to claim 1, wherein the voltage comparison circuit comprises:
a first comparator for comparing the voltage level of the input signal with the voltage level of the first threshold voltage to perform the binarization determination with respect to the input signal, and generating an output signal based on the determination result;
a second comparator for comparing the voltage level of the input signal with the voltage level of the second threshold voltage to perform the binarization determination with respect to the input signal, and generating an output signal based on the determination result; and
a flip-flop having a set input terminal for receiving the output signal from the first comparator and a reset input terminal for receiving the output signal from the second comparator.

5. The hysteresis comparator according to claim 1, wherein:
the top peak detector comprises:
a top peak output terminal for outputting the top peak detecting voltage;
a first capacitor connected to the top peak output terminal; and
a charging circuit for charging the first capacitor to the voltage level of the input signal when the voltage level of the input signal is higher than a voltage level at the top peak output terminal; and
the bottom peak detector comprises:
a bottom peak output terminal for outputting the bottom peak detecting voltage;
a second capacitor connected to the bottom peak output terminal; and
a charging circuit for charging the second capacitor to the voltage level of the input signal when the voltage level of the input signal is lower than a voltage level at the bottom peak output terminal.

6. The hysteresis comparator according to claim 5, wherein the top peak detector and the bottom peak detector further comprise discharging resistors connected in parallel respectively to the first and second capacitors.

7. The hysteresis comparator according to claim 5, wherein the top peak output terminal and the bottom peak output terminal are interconnected via a resistive element.

8. The hysteresis comparator according to claim 1, wherein the top peak detecting voltage and the bottom peak detecting voltage are consecutively updated.

9. The hysteresis comparator according to claim 1, wherein the first and second threshold voltages vary with the voltage level of the input signal.

10. The hysteresis comparator according to claim 9, wherein the first and second threshold voltages vary following the top peak detecting voltage and the bottom peak detecting voltage.

11. The hysteresis comparator according to claim 1, wherein the top peak detecting voltage and the bottom peak detecting voltage vary following each other's voltage levels.
